(19) United States
(12) Patent Application Publication
(10) Pub. No.: US 2002/0000584 A1
(43) Pub. Date: Jan. 3, 2002

(54) Semiconductor structure and device including a monocrystalline conducting layer and method for fabricating the same

(75) Inventors: Kurt W. Eisenbeiser, Tempe, AZ (US); Ravindranath Droopad, Chandler, AZ (US); Zhiyi Yu, Gilbert, AZ (US)

Correspondence Address: MOTOROLA, INC., CORPORATE LAW DEPARTMENT - #56-238, 3102 NORTH 56TH STREET, PHOENIX, AZ, 85018, US

(73) Assignee: Motorola, Inc.

(21) Appl. No.: 09/755,340

(22) Filed: Jan. 5, 2001

Related U.S. Application Data
(63) Continuation-in-part of application No. 09/607,207, filed on Jun. 28, 2000.

(51) Int. Cl. H01L 21/00; H01L 31/0328; H01L 29/76

(52) U.S. Cl. 257/295; 438/3; 257/190; 257/43; 438/85

(57) ABSTRACT

High quality epitaxial layers of conductive monocrystalline materials can be grown overlying monocrystalline substrates (22) such as large silicon wafers by forming a compliant substrate for growing the monocrystalline layers. One way to achieve the formation of a compliant substrate includes first growing an accommodating buffer layer(24) on a silicon wafer (22). The accommodating buffer layer (24) is a layer of monocrystalline material spaced apart from the silicon wafer (22) by an amorphous interface layer (28) of silicon oxide. The amorphous interface layer (28) dissipates strain and permits the growth of a high quality monocrystalline accommodating buffer layer (24).

### CROSS REFERENCE TO RELATED APPLICATIONS

This application is a continuation-in-part of U.S. patent application Ser. No. 09/607,207, filed Jun. 28, 2000 by the assignee hereof.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a monocrystalline conductive material layer.

### BACKGROUND OF THE INVENTION

Semiconductor devices often include multiple layers of conductive, insulative, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monocrystalline thin films on a foreign substrate such as silicon (Si). To achieve optimal characteristics of the various monocrystalline layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a relatively low cost. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true, two-dimensional growth can be achieved for the formation of quality semiconductor structures, devices and integrated circuits having a grown monocrystalline film of the same crystal orientation as an underlying substrate. This monocrystalline material layer may be comprised of a semiconductor material, a compound semiconductor material, or other types of material such as metals.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a semiconductor device structure including a monocrystalline conducting film in accordance with the invention; and

FIG. 6 illustrates a portion of the device structure of FIG. 5 in greater detail.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

The present invention generally relates to a semiconductor structure including a monocrystalline layer of conductive material. As explained in greater detail below, the conductive layer of such structures may be used to form ground planes and heat sinks for microelectronic devices such as radio frequency monolithic microwave integrated circuits (RF MMICs).

FIG. 1 illustrates schematically, in cross section, a portion of a semiconductor structure 20, suitable for use in fabricating RF MMIC devices, in accordance with an embodiment of the invention. Semiconductor structure 20 includes a monocrystalline substrate 22, an accommodating buffer layer 24 comprising a monocrystalline material, and a monocrystalline conductive layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and conductive material layer 26. As will be explained more fully below, the template layer helps to initiate the epitaxial growth of the conductive material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor wafer, preferably of large diameter. The wafer can be of, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline conductive layer 26.

Accommodating buffer layer 24 is preferably a monocrystalline oxide or nitride material selected for its crystalline compatibility with the underlying substrate and with the overlying conductive layer. For example, the material could be an oxide or nitride having a lattice structure closely matched to the substrate and to the subsequently applied monocrystalline conductive layer. Materials that are suitable for the accommodating buffer layer include metal oxides such as the alkali earth metal titanates, alkali earth metal zirconates, alkali earth metal hafnates, alkali earth metal tantalates, alkali earth metal ruthenates, alkali earth metal niobates, alkali earth metal vanadates, perovskite oxides such as alkali earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline conductive layer 26 can be selected, as desired, for a particular structure or application. In accordance with exemplary embodiments of the present invention, layer 26 comprises an electrically conductive oxide such as strontium ruthenate (Sr₂RuO₄); a thermally conductive oxide such as LaCoO₃ or BeO₂; a metal such as nickel aluminum (NiAl), iron aluminum (FeAl); a combination of such materials; or a combination of layers of such materials.

Appropriate materials for template 30 are discussed below. Suitable template materials chemically bond to the surface of the accommodating buffer layer 24 at selected sites and provide sites for the nucleation of the epitaxial growth of monocrystalline conductive layer 26. When used, template layer 30 has a thickness ranging form about 1 to about 10 monolayers.

FIG. 2 illustrates, in cross section, a portion of a semiconductor structure 40 in accordance with a further embodiment of the invention. Structure 40 is similar to the previously described semiconductor structure 20, except that an additional, optional buffer layer 32 is formed above layer 26 and structure 40 includes an additional monocrystalline material layer 38. When used, the additional buffer layer is positioned between conductive layer 26 and the overlying layer 40. The additional buffer layer serves to provide a lattice compensation when the lattice constant of the conducting layer cannot be adequately matched to the overlying monocrystalline material layer. Although not illustrated, a structure in accordance with another embodiment of the invention may include, either in lieu of or in addition to layer 32, a buffer layer interposed between the accommodating buffer layer and the conductive material layer.

In accordance with another embodiment of the invention, accommodating buffer layer 24 forms a conducting layer suitable for use as a ground plane or a heat sink. In this case, a structure includes substrate 22, amorphous layer 28, accommodating buffer layer 24 (which is now also the conductive layer), and additional monocrystalline material layer 38. As noted above, materials that may be used to form layer 24, which are also conductive, include strontium ruthenate.

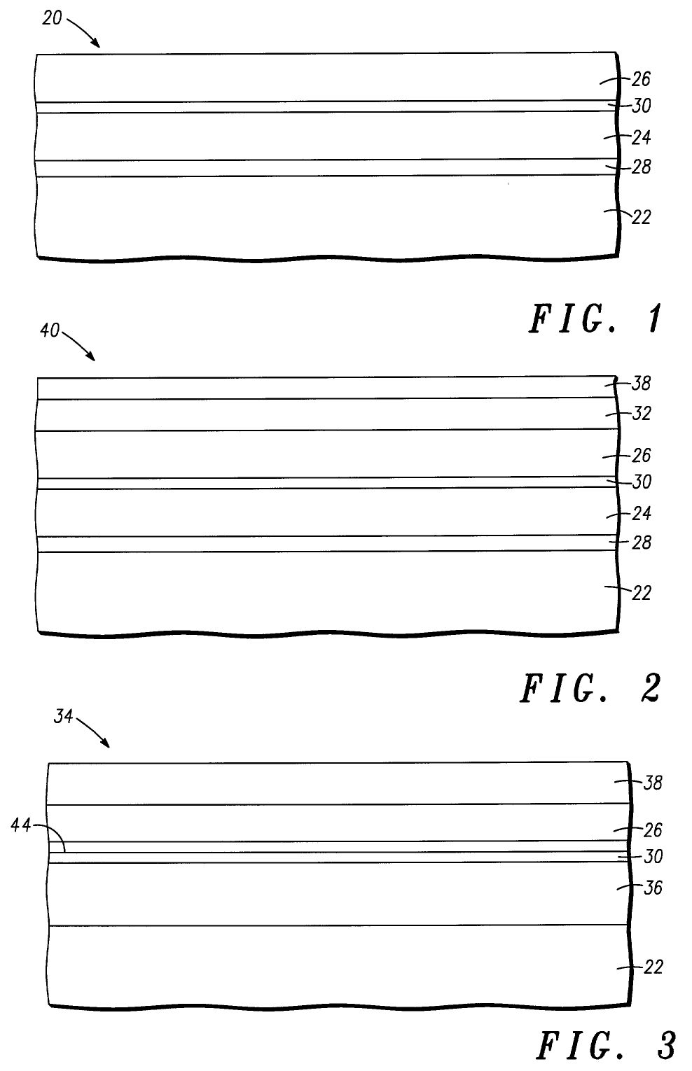

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and includes additional monocrystalline layer 38 and a cap layer 44.

As explained in greater detail below, amorphous layer 36 may be formed by first forming an accommodating buffer layer and an amorphous interface layer in a similar manner to that described above. Cap layer 44 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and monocrystalline conductive layer 26 (subsequent to layer 44 formation) relieves stresses between layers 22 and 26 and provides a true compliant substrate for subsequent processing—e.g., layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous layer, may be better for growing monocrystalline material layers because any stain in the monocrystalline accommodating buffer layer may be reduced as the layer is caused to become amorphous.

In accordance with one embodiment of the present invention, cap layer 44 serves as an anneal cap during layer 36 formation and as a template for subsequent monocrystalline layer 26 formation. Accordingly, layer 44 is preferably thick enough to provide a suitable template for layer 26 growth (at least about one monolayer) and thin enough to allow layer 44 to form as a substantially defect free monocrystalline material.

In accordance with another embodiment of the invention, layer 26 may serve as an anneal cap. In this case, layer 44 is not required to form the structure of the present invention.

Additional monocrystalline layer 38 may comprise any material suitable for semiconductor manufacturing. For example, layer 38 may include a semiconductor or compound semiconductor material, such that microelectronic devices may be formed using layer 38. Alternatively, layer 38 may include insulating films using materials described above in connection with layer 24.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃, where z ranges from 0 to 1, and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the conductive layer from the substrate to obtain the desired electrical and/or optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline conductive layer 26 is a monocrystalline metal such NiAl. In this case, a subsequently formed monocrystalline layer may include about 1 nm to about 100 micrometers (μm) GaAs, which is closely lattice matched to NiAl.

To facilitate the epitaxial growth of the conductive layer on the monocrystalline oxide, a template layer is formed by capping the oxide layer. The template layer is preferably 1-10 monolayers of Sr—Ni—O or Sr—Al—O. Similarly, exemplary templates for subsequent growth of GaAs over the conductive layer include 1-10 monolayers of AlAs or Ni—As.

### EXAMPLE 2

In accordance with a further embodiment of the invention, monocrystalline substrate 22 is a silicon substrate as described above. The accommodating buffer layer is a monocrystalline oxide in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate silicon lattice structure.

An accommodating buffer layer formed of these materials is suitable for the growth of a monocrystalline material layer which comprises monocrystalline metal such as FeAl, which in turn is suitable for subsequent growth of additional monocrystalline material layers of compound semiconductor materials in the indium phosphide (InP) system. Exemplary template layer materials for these monocrystalline accommodating buffer layer materials include Sr—Al—O and Sr—Fe—O.

In this system, the additional monocrystalline layer 38 materials can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of Al—As or Al—P.

### EXAMPLE 3

In accordance with a further embodiment of the invention, conductive layer 26 includes a monocrystalline oxide such as Sr₂RuO₄ or LaCoO₃ formed above accommodating buffer layer 24. The conductive oxide layer may be formed above, for example, a Sr₂Ba_{1-z}TiO₃ accommodating buffer layer, as describe above. Alternatively, the Sr₂RuO₄ may serve as both the accommodating buffer and conductive layers. In this case, additional monocrystalline material may be formed directly above the accommodating buffer layer, using an appropriate template, as described above.

### EXAMPLE 4

This embodiment of the invention is an example of structure 40 illustrated in FIG. 2. Substrate 22, accommodating buffer layer 24, and monocrystalline conductive layer 26 can be similar to those described in example 1. In addition, an (optional) additional buffer layer 32 serves to alleviate any strains that might result from a mismatch of the crystal lattice of the conductive layer and the lattice of the subsequently formed layer of additional monocrystalline material. Buffer layer 32 can be, for example, a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying conductive material and the overlying additional monocrystalline material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-aluminum (Ge—Al) or germanium-nickel (Ge—Ni) having a thickness of about one monolayer can be used as a nucleating site.

### EXAMPLE 5

This example also illustrates materials useful in a structure 40 as illustrated in FIG. 2. Substrate material 22, accommodating buffer layer 24, monocrystalline conductive layer 26 and template layer 30 can be the same as those described above in example 2. In addition, (optional) additional buffer layer 32 may be inserted between the conductive layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The buffer layer preferably has a thickness of about 10-30 nm. Varying the composition of the buffer layer from GaAs to InGaAs serves to provide a lattice match between the underlying monocrystalline conductive material and the overlying layer of additional monocrystalline material.

### EXAMPLE 6

This example provides exemplary materials useful in structure 34, as illustrated in FIG. 3. Substrate material 22, template layer 30, and monocrystalline conductive layer 26 may be the same as those described above in connection with example 1.

Amorphous layer 36 is an amorphous oxide layer which is suitably formed of a combination of amorphous intermediate layer materials (e.g, layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over monocrystalline conductive material of layer 26. In accordance with one embodiment of the invention, layer 38 includes 1 monolayer to about 100 nm thick of semiconductor material such as Group IIIA and VA elements (III-V semiconductor compounds), mixed III-V compounds, Group II(A or B) and VIA elements (II-VI semiconductor compounds), mixed II-VI compounds, and Group IV compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), silicon, silicon carbide, and the like.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

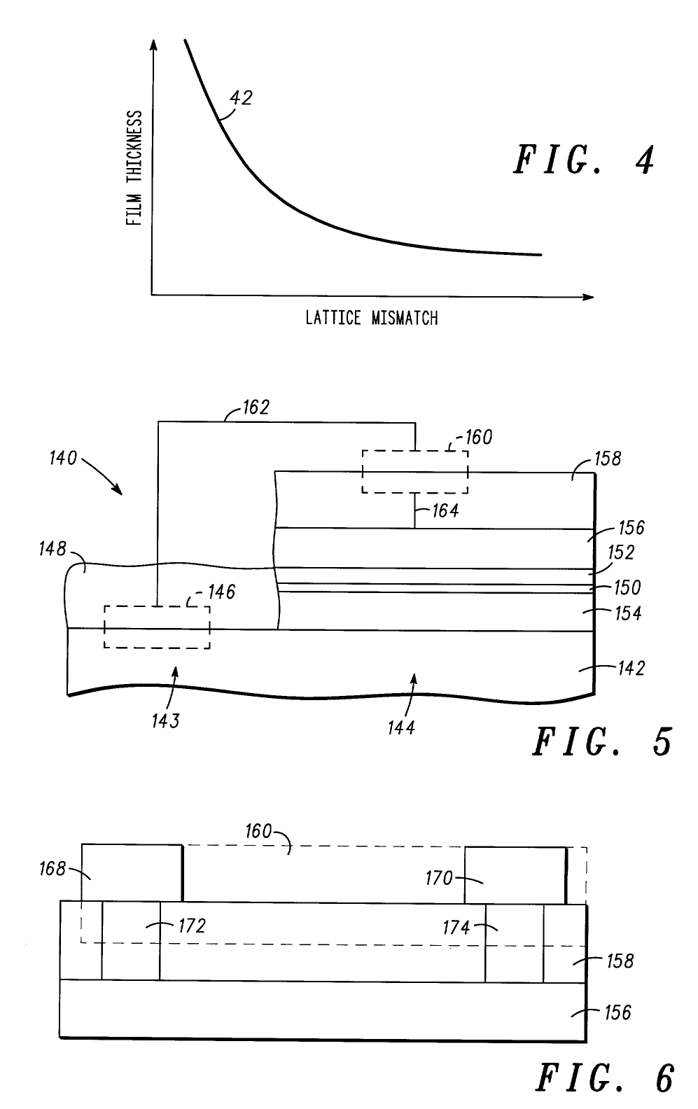

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline conductive material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. In some instances, a crystalline buffer layer between the host accommodating buffer layer and the grown monocrystalline material layer can be used to reduce strain in the grown monocrystalline material layer that might result from small differences in lattice constants. Better crystalline quality in the grown monocrystalline conductive material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow an accommodating buffer layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkali earth metals or combinations of alkali earth metals in an MBE apparatus. In the case where strontium is used, the substrate is then heated to a temperature of about 850° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkali earth metal oxide, such as strontium oxide, strontium barium oxide, or barium oxide, onto the substrate surface by MBE at a low temperature and by subsequently heating the structure to a temperature of about 850° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stochiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered monocrystal with the crystalline orientation rotated by 45° with respect to the ordered 2×1 crystalline structure of the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired conductive monocrystalline material. For example, the MBE growth of the strontium titanate monocrystalline layer can be capped by terminating the growth with 1-2 monolayers of titanium, 1-2 monolayers of titanium-oxygen or with 1-2 monolayers of strontium-oxygen. Next, conductive material such as NiAl can be epitaxially grown over the accommodating buffer layer by using a Sr—Al or Sr—Al—O template.

The structure illustrated in FIG. 2 can be formed by the process discussed above with the addition of an additional buffer layer deposition step. The buffer layer is formed overlying the conductive layer before the deposition of the additional monocrystalline layer. If the buffer layer is a monocrystalline material comprising a compound semiconductor superlattice, such a superlattice can be deposited, by MBE for example, on the template described above.

Structure 34, illustrated in FIG. 3, may be formed by growing an accommodating buffer layer, forming an amorphous oxide layer over substrate 22, and growing cap layer 44 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 44. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline cap 44 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 44 may be required to prevent degradation of layer 44 during the anneal process. For example, when layer 44 includes GaAs, the anneal environment preferably includes an overpressure of arsenic to mitigate degradation of layer 44.

As noted above, layer 44 of structure 34 may include any materials suitable for either of layers 32 or 26. Accordingly, any deposition or growth methods described in connection with either layer 32 or 26 may be employed to deposit layer 44.

The process described above illustrates a process for forming a semiconductor structure including a silicon substrate, an overlying oxide layer, and a monocrystalline conductive material layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkali earth metal titanates, zirconates, hafnates, tantalates, vanadates, ruthenates, and niobates, peroskite oxides such as alkali earth metal tin-based perovskites, lanthanum aluminate, lanthanum scandium oxide, and gadolinium oxide can also be grown. Further, by a similar process such as MBE, other monocrystalline material layers comprising III-V and II-VI monocrystalline compound semiconductors, Group IV semiconductors, metals and other materials can be deposited.

Each of the variations of monocrystalline material layer and monocrystalline accommodating buffer layer uses an appropriate template for initiating the growth of the monocrystalline material layer. For example, if the accommodating buffer layer is an alkali earth metal zirconate, the oxide can be capped by a thin layer of zirconium. Similarly, if the monocrystalline oxide accommodating buffer layer is an alkali earth metal hafnate, the oxide layer can be capped by a thin layer of hafnium. In a similar manner, strontium titanate can be capped with a layer of strontium or strontium and oxygen and barium titanate can be capped with a layer of barium or barium and oxygen. Each of these depositions can be followed by the deposition of desired monocrystalline conductive material.

FIG. 5 illustrates schematically, in cross section, a device structure 140 in accordance with a further embodiment of the invention. Device structure 140 includes a monocrystalline semiconductor substrate 142, preferably a monocrystalline silicon wafer. Monocrystalline semiconductor substrate 142 includes two regions, 143 and 144. An electrical semiconductor component generally indicated by the dashed line 146 is formed, at least partially, in region 143. Electrical component 146 can be a resistor, a capacitor, an active semiconductor component such as a diode or a transistor or an integrated circuit such as a CMOS integrated circuit. For example, electrical semiconductor component 146 can be a CMOS integrated circuit configured to perform digital signal processing or another function for which silicon integrated circuits are well suited. The electrical semiconductor component in region 143 can be formed by conventional semiconductor processing as is well known and widely practiced in the semiconductor industry. A layer of insulating material 148 such as a layer of silicon oxide or the like may overlie electrical semiconductor component 146.

Insulating material 148 and any other layers that may have been formed or deposited during the processing of semiconductor component 146 in region 143 are removed from the surface of region 144 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 144 and is reacted with the oxidized surface to form a first template layer (not shown). In accordance with one embodiment of the invention a monocrystalline oxide layer is formed overlying the template layer by a process of molecular beam epitaxy. Reactants including barium, titanium and oxygen are deposited onto the template layer to form the monocrystalline oxide layer. During the deposition, the partial pressure of oxygen is initially set near the minimum necessary to fully react with the barium and titanium to form the monocrystalline barium titanate layer. As the monocrystalline oxide forms, the partial pressure of oxygen is increased to form an amorphous layer between the growing crystalline layer and the substrate.

In accordance with an embodiment of the invention, the step of depositing the monocrystalline oxide layer is terminated by forming a layer 150, which can be 1-10 monolayers of titanium, barium, strontium, barium and oxygen, titanium and oxygen, or strontium and oxygen. A cap layer 152 of a monocrystalline material is then deposited overlying the second template layer by a process of molecular beam epitaxy.

In accordance with one aspect of the present embodiment, after layer 152 formation, the monocrystalline titanate layer is exposed to an anneal process such that the titanate layer forms an amorphous oxide layer 154. A monocrystalline conductive layer 156 and an additional monocrystalline material layer 158 are then epitaxially grown over layer 152, using the techniques described above.

In accordance with a further embodiment of the invention, a semiconductor component, generally indicated by a dashed line 160 is formed, at least partially, in layer 158, which is formed of GaAs. Semiconductor component 160 can be formed by processing steps conventionally used in the fabrication of gallium arsenide or other III-V compound semiconductor material devices. Semiconductor component 160 can be any active or passive component, and preferably is a high frequency MMIC, or another component that utilizes and takes advantage of the physical properties of compound semiconductor materials and of conductive layer 156, which may form a heat sink or ground plane for device 160. A metallic conductor schematically indicated by the line 162 can be formed to electrically couple device 146 and device 160, thus implementing an integrated device that includes at least one component formed in the silicon substrate and one device formed in the monocrystalline material layer.

In accordance with one embodiment of the invention, layer 156 functions as a ground plane for device 160. In this case, device 160 is coupled to ground plane layer 156 using a conductor illustrated by line 164. Thus, a high speed device can be coupled to a ground plane, through a relatively short distance, without requiring back-side thinning of substrate 142. In accordance with an alternate embodiment of the invention, layer 156 may form a heat sink as noted above.

Although illustrative structure 140 has been described as a structure formed on a silicon substrate 142 and having a barium (or strontium) titanate layer and a gallium arsenide layer 158, similar devices can be fabricated using other monocrystalline substrates, oxide layers and other monocrystalline material layers as described elsewhere in this disclosure.

FIG. 6 illustrates a portion of structure 140 in greater detail, showing an exemplary electrical connection between a portion of device 160 and layer 156. In the illustrative example, device 160 includes source contacts 168 and 170. The source contacts are coupled to layer 156 using conductive plugs 172 and 174, formed using conventional semiconductor processing techniques.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as conducting and insulating layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g., conventional compound semiconductor wafers).

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a monocrystalline substrate;
an accommodating buffer layer formed on the substrate;
a template formed on the accommodating buffer layer; and
a monocrystalline conductive material layer formed overlying the template.

2. The semiconductor structure of claim 1, further comprising an additional monocrystalline material layer formed above the monocrystalline conductive material layer.

3. The semiconductor structure of claim 2, wherein the additional monocrystalline material layer comprises a semiconductor material.

4. The semiconductor structure of claim 2, wherein the additional monocrystalline material layer comprises a compound semiconductor material.

5. The semiconductor structure of claim 2, wherein the additional monocrystalline material layer comprises GaAs.

6. The semiconductor structure of claim 2, wherein the additional monocrystalline material layer comprises InP.

7. The semiconductor structure of claim 2, wherein the additional monocrystalline material layer comprises InGaAs.

8. The semiconductor structure of claim 1, wherein the monocrystalline conductive material layer is thermally conductive.

9. The semiconductor structure of claim 1, wherein the monocrystalline conductive material layer is electrically conductive.

10. The semiconductor structure of claim 1, wherein the monocrystalline conductive material layer comprises a material selected from the group consisting of Sr₂RuO₄, LaCoO₃, BeO₂, FeAl, and NiAl.

11. The semiconductor structure of claim 1, wherein the accommodating buffer layer comprises a material selected from the group consisting of alkali earth metal titanates, alkali earth metal zirconates, alkali earth metal hafnates, alkali earth metal tantalates, alkali earth metal ruthenates, alkali earth metal niobates, alkali earth metal vanadates, perovskite oxides such as alkali earth metal tin-based perovskites, lanthanum aluminate, lanthanum scandium oxide, gadolinium oxide, gallium nitride, aluminum nitride, and boron nitride.

12. The semiconductor structure of claim 1, wherein the accommodating buffer layer is amorphous.

13. The semiconductor structure of claim 1, wherein the accommodating buffer layer is monocrystalline.

14. The semiconductor structure of claim 1, further comprising an amorphous material layer formed between the monocrystalline substrate and the accommodating buffer layer.

15. The semiconductor structure of claim 1, further comprising an additional buffer layer formed above the monocrystalline conductive material layer.

16. A semiconductor device comprising the structure of claim 1.

17. A process for fabricating a semiconductor structure comprising the steps of:
providing a monocrystalline substrate;
epitaxially growing a accommodating buffer layer overlying the monocrystalline substrate;
forming an amorphous layer on the monocrystalline substrate during the growth of the accommodating buffer layer; and
forming a monocrystalline conductive layer over the accommodating buffer layer.

18. The process of claim 17, further comprising the step of annealing the accommodating buffer layer to convert the accommodating buffer layer structure from monocrystalline to amorphous.

19. The process of claim 17, further comprising the step of epitaxially growing an additional monocrystalline layer above the monocrystalline conductive layer.

20. The process of claim 19, wherein the step of growing an additional monocrystalline layer includes growing a semiconductor material layer.

21. The process of claim 20, wherein the step of growing a semiconductor material layer includes epitaxially forming a layer comprising InP.

22. The process of claim 20, wherein the step of growing a semiconductor material layer includes epitaxially forming a layer comprising GaAs.

23. The process of claim 20, wherein the step of growing a semiconductor material layer includes epitaxially forming a layer comprising InGaAs.

24. A semiconductor device formed using the process of claim 17.

25. A semiconductor device comprising:
a monocrystalline substrate;
an accommodating buffer layer disposed above the monocrystalline substrate;
a template formed above the accommodating buffer layer;
a monocrystalline conductive layer formed above the template; and
an additional monocrystalline layer formed above the monocrystalline conductive layer.

26. The semiconductor device of claim 25, wherein the monocrystalline conductive layer forms a ground plane of the device.

27. The semiconductor device of claim 25, wherein the monocrystalline conductive layer forms a heat sink.

28. The semiconductor device structure of claim 25, further comprising an electronic component formed at least partially within the monocrystalline substrate.

29. The semiconductor device structure of claim 25, further comprising an electronic component formed at least partially within the additional monocrystalline material.

30. The semiconductor structure of claim 29, wherein the electronic component comprises a microwave device.

31. The semiconductor device structure of claim 25, further comprising an electrical connection between the additional monocrystalline layer and the monocrystalline conductive layer.

32. A semiconductor device comprising:
a monocrystalline substrate;
a monocrystalline conductive layer formed above the substrate; and
an additional monocrystalline layer formed above the monocrystalline conductive layer.
